(19) United States
(12) Patent Application Publication
(10) Pub. No.: US 2026/0245830 A1
(43) Pub. Date: Aug. 20, 2026

(54) CHARGED PARTICLE BEAM WRITING APPARATUS, DRIFT AMOUNT CALCULATION METHOD, AND CHARGED PARTICLE BEAM WRITING METHOD

(71) Applicant: NuFlare Technology, Inc., Yokohama-shi (JP)

(72) Inventors: Jumpei YASUDA, Yokohama-shi (JP); Toru HINATA, Yokohama-shi (JP); Michihiko IKEDA, Yokohama-shi (JP)

(73) Assignee: NuFlare Technology, Inc., Yokohama-shi (JP)

(21) Appl. No.: 19/640,949

(22) Filed: Apr. 7, 2026

Related U.S. Application Data
(63) Continuation of application No. PCT/JP2024/026392, filed on Jul. 24, 2024.

(30) Foreign Application Priority Data
Nov. 13, 2023 (JP) 2023-193098

(51) Int. Cl. H01J 37/304; H01J 37/12; H01J 37/147; H01J 37/244; H01J 37/317

(52) U.S. Cl. CPC H01J 37/3045; H01J 37/12; H01J 37/1471; H01J 37/244; H01J 37/3174; H01J 2237/30461

(57) ABSTRACT

In one embodiment, a charged particle beam writing apparatus includes a charged particle beam source configured to emit a charged particle beam that is irradiated onto a substrate to be written, a deflector configured to deflect the charged particle beam to a desired irradiation position on the substrate, a detector configured to detect electrons reflected or emitted from the substrate toward the deflector, a correction amount generation unit configured to calculate a drift amount of the charged particle beam irradiated onto the substrate from a current amount obtained from the detected electrons and a time elapsed from detecting the current to performing correction, and to generate a correction amount for irradiation position misalignment based on the drift amount, and a control unit configured to correct the irradiation position based on shot data of the charged particle beam generated from writing data and the correction amount.

### CROSS-REFERENCE TO RELATED APPLICATIONS

This application is a continuation of International Application No. PCT/JP2024/026392, filed on Jul. 24, 2024, which is hereby incorporated by reference in its entirety.

### FIELD

The present invention relates to a charged particle beam writing apparatus, a drift amount calculation method, and a charged particle beam writing method.

### BACKGROUND

With the increase in the integration density of LSIs, the required circuit linewidths for semiconductor devices have become finer year by year. In order to form a desired circuit pattern on a semiconductor device, a method is employed in which a high-precision original pattern formed on quartz (a mask, or, in particular, one used in a stepper or scanner, also called a reticle) is reduced and transferred onto a wafer using a reduction-projection exposure apparatus. The high-precision original pattern is written by an electron beam writing apparatus, and so-called electron-beam lithography technology is used.

In an electron beam writing apparatus, a phenomenon called beam drift may occur, in which the irradiation position of the electron beam shifts over time during writing due to various factors. For example, contamination may adhere to the irradiation system such as the deflection electrodes of the writing apparatus, and the contamination may become charged by scattered electrons from the substrate being written, thereby causing beam drift. To cancel this beam drift, drift correction is performed.

In conventional drift correction, the beam irradiation position is measured by scanning a measurement mark with the electron beam at predetermined timings during the writing process, and the difference from the previous measurement value is used as the drift correction amount. However, with this method, when the drift trend changes significantly, the correction error becomes large, resulting in degradation of writing accuracy. If the measurement interval of the beam irradiation position is shortened in order to suppress the correction error, throughput decreases.

### PRIOR ART DOCUMENTS

### Patent Documents

[Patent Document 1] Japanese Unexamined Patent Publication No. HEI 10-256112
[Patent Document 2] Japanese Unexamined Patent Publication No. HEI 8-274002
[Patent Document 3] Japanese Unexamined Patent Publication No. 2007-019246

### SUMMARY OF THE INVENTION

It is an object of the present invention to provide a charged particle beam writing apparatus, a drift amount calculation method, and a charged particle beam writing method that are capable of correcting beam drift in real time during the writing process.

According to one aspect of the present invention, a charged particle beam writing apparatus includes a charged particle beam source configured to emit a charged particle beam that is irradiated onto a substrate to be written, a deflector configured to deflect the charged particle beam to a desired irradiation position on the substrate, a detector configured to detect electrons reflected or emitted from the substrate toward the deflector, a correction amount generation unit configured to calculate a drift amount of the charged particle beam irradiated onto the substrate from a current amount obtained from the detected electrons and a time elapsed from detecting the current to performing correction, and to generate a correction amount for irradiation position misalignment based on the drift amount, and a control unit configured to correct the irradiation position based on shot data of the charged particle beam generated from writing data and the correction amount.

According to one aspect of the present invention, a drift amount calculation method includes emitting a charged particle beam to be irradiated onto a substrate to be written, deflecting the charged particle beam to a desired irradiation position on the substrate, generating shot data from writing data, the shot data including a shot position and beam on/off time for each shot, detecting electrons reflected or emitted from the substrate toward the deflector, and calculating a first drift amount of the irradiation position of the charged particle beam on the substrate based on a current amount obtained from the detected electrons and a time elapsed from detecting the current to performing correction.

According to one aspect of the present invention, a charged particle beam writing method includes emitting a charged particle beam to be irradiated onto a substrate to be written, deflecting the charged particle beam to a desired irradiation position on the substrate, generating shot data from writing data, the shot data including a shot position and beam on/off time for each shot, detecting electrons reflected or emitted from the substrate toward the deflector, calculating a first drift amount of the irradiation position of the charged particle beam on the substrate based on a current amount obtained from the detected electrons and a time elapsed from detecting the current to performing correction, calculating a correction amount for a positional deviation of irradiation based on the first drift amount, and correcting the irradiation position based on the shot data and the correction amount.

### Effects of the Invention

According to the present invention, beam drift during the writing process can be corrected in real time.

### BRIEF DESCRIPTION OF THE DRAWINGS

FIG. 1 is a schematic diagram of an electron beam writing apparatus according to an embodiment of the present invention.

FIG. 2 is a perspective view of a first shaping aperture and a second shaping aperture.

FIG. 3 is a conceptual diagram illustrating a deflection region.

FIGS. 4A and 4B are diagrams showing examples of arrangements of the electrodes of the detector.

FIG. 5 is a diagram illustrating a configuration example of a voltage measuring device.

### DETAILED DESCRIPTION

Hereinafter, embodiments of the present invention will be described with reference to the drawings. In the present embodiment, an example using an electron beam as the charged particle beam will be described. However, the charged particle beam is not limited to an electron beam and may also be an ion beam or the like.

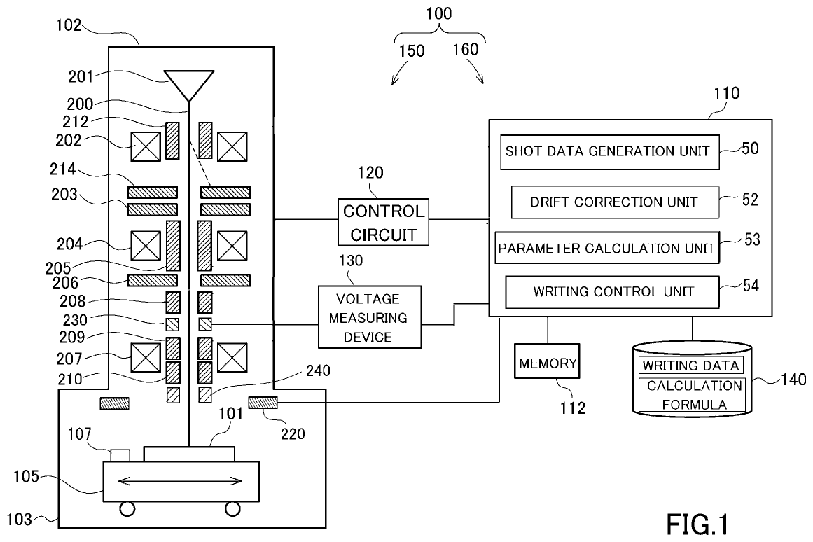

FIG. 1 is a conceptual diagram showing the configuration of a writing apparatus in the embodiment. In FIG. 1, the writing apparatus 100 includes a writing unit 150 and a control unit 160. The writing unit 150 includes an electron optical column 102 and a writing chamber 103. Inside the electron optical column 102, an electron gun 201, an illumination lens 202, a blanking deflector 212, a blanking aperture substrate 214, a first shaping aperture substrate 203, a projection lens 204, a shaping deflector 205, a second shaping aperture substrate 206, an objective lens 207, a main deflector 208, a sub-deflector 209, a sub-sub deflector 210, a detector 230, and an electrostatic correction lens 240 are arranged.

Inside the writing chamber 103, an XY stage 105 that can move in the X and Y directions is arranged. On the XY stage 105, a substrate 101 to be written, coated with resist, is placed. The substrate 101 includes an exposure mask, a silicon wafer, a mask blank, or the like for manufacturing a semiconductor device.

On the XY stage 105, at a position separate from the region where the substrate 101 is placed, a reflection mark 107 for measuring the drift amount of the electron beam is provided. The reflection mark 107 is, for example, in a cross shape or dot shape, and is formed of a heavy metal such as tantalum or tungsten on a silicon substrate.

Above the XY stage 105, a detector 220 is provided for detecting reflected electrons that are reflected by the reflection mark 107 when the reflection mark 107 is scanned with the electron beam. The reflected electrons detected by the detector 220 are converted into a current value and supplied to a control computer 110. The control computer 110 can calculate the irradiation position (beam position) of the electron beam based on a change in the current value.

The electron beam 200 emitted from the electron gun 201 (emission unit) provided in the electron optical column 102 is switched by the blanking deflector 212, while passing through the blanking deflector 212, to either irradiate or not irradiate the electron beam onto the substrate 101.

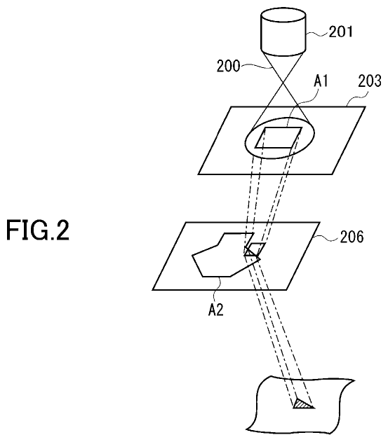

The electron beam 200 is irradiated by the illumination lens 202 onto a first shaping aperture substrate 203 having a rectangular opening A1 (see FIG. 2). By passing through the opening A1 of the first shaping aperture substrate 203, the electron beam 200 is shaped into a rectangular form.

The electron beam 200 forming the first aperture image after passing through the first shaping aperture substrate 203 is projected by the projection lens 204 onto a second shaping aperture substrate 206 having a variable shaping opening A2 (see FIG. 2). At this time, the first aperture image projected onto the second shaping aperture substrate 206 is deflection-controlled by the shaping deflector 205, allowing the shape and dimensions of the electron beam passing through the variable shaping opening A2 to be changed (performing variable shaping).

The electron beam 200 forming the second aperture image after passing through the variable shaping opening A2 of the second shaping aperture substrate 206 is focused by the objective lens 207 and deflected by the main deflector 208, the sub-deflector 209, and the sub-sub deflector 210, and is irradiated onto the substrate 101 placed on the continuously moving XY stage 105.

The control unit 160 includes a control computer 110, a memory 112, a control circuit 120, a voltage measuring device 130, and a storage device 140.

The control computer 110 includes a shot data generation unit 50, a drift correction unit 52 (correction amount generating unit), a parameter calculation unit 53, and a writing control unit 54. Each of the functions of the shot data generation unit 50, the drift correction unit 52, the parameter calculation unit 53, and the writing control unit 54 may be implemented in software or in hardware.

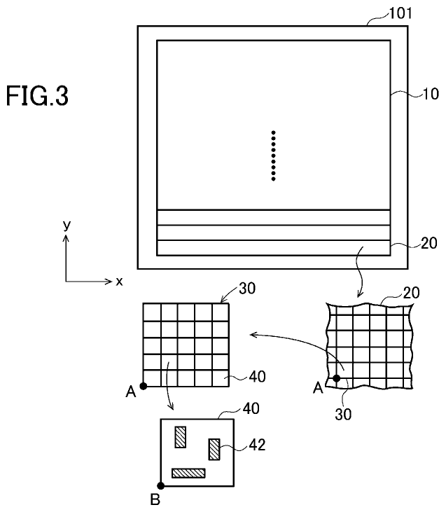

FIG. 3 is a conceptual diagram for explaining the deflection region. As shown in FIG. 3, the writing region 10 of the substrate 101 is virtually divided into a plurality of stripe regions 20 in a strip shape, for example, in the y-direction, within the deflectable range of the main deflector 208. Then, regions obtained by dividing the stripe regions 20 in the x-direction within the deflectable range of the main deflector 208 constitute the deflection regions (main deflection regions) of the main deflector 208.

The main deflection region is virtually divided into a plurality of subfields (SF) 30 in a mesh pattern, according to the deflectable size of the sub-deflector 209. Each SF 30 is further virtually divided into a plurality of under-subfields 40 in a mesh pattern according to the deflectable size of the sub-sub deflector 210. (Here, under-subfield refers to a third deflection, abbreviated as “TF” for Tertiary Deflection Field; the same applies below.) Shot patterns are written at each shot position 42 within each TF 40.

The control circuit 120 applies a deflection voltage for blanking control to the blanking deflector 212. The electron beam 200 is deflected by this deflection voltage, and blanking control for each shot is performed.

The control circuit 120 applies a deflection voltage for shaping deflection to the shaping deflector 205. The electron beam 200 is deflected to a specific position on the second shaping aperture substrate 206 by this deflection voltage, forming an electron beam having the desired dimensions and shape.

The control circuit 120 applies a deflection voltage for main deflection control to the main deflector 208. By this deflection voltage, the electron beam 200 is deflected and directed to a reference position A of a predetermined subfield (SF), which is virtually divided in a mesh pattern for each shot (for example, the center position or the lower-left corner of the corresponding SF). In addition, when the XY stage 105 moves continuously during writing, the deflection voltage also includes a tracking deflection voltage that follows the stage movement.

The control circuit 120 applies a deflection voltage for sub-deflection control to the sub-deflector 209. By this deflection voltage, the electron beam 200 is deflected and directed to a reference position B of a TF 40, which is the minimum deflection region for each shot (for example, the center position or the lower-left corner of the corresponding TF).

The control circuit 120 applies a deflection voltage for sub-sub deflection control to the sub-sub deflector 210. By this deflection voltage, the electron beam 200 is deflected and directed to each shot position 42 within the TF 40 for each shot.

In the writing apparatus 100, writing is performed for each stripe region 20 using multiple stages of deflectors. As an example, three-stage deflectors such as the main deflector 208, the sub-deflector 209, and the sub-sub deflector 210 are used. In the configuration shown in FIG. 1, the main deflector 208, the sub-deflector 209, and the sub-sub deflector 210 are arranged in order from the upstream side in the traveling direction of the electron beam, but the arrangement order of the three-stage deflectors is not limited to this.

While the XY stage 105 continuously moves, for example, in the −x direction, writing progresses in the x direction for the first stripe region 20. After completing writing of the first stripe region 20, writing of the second stripe region 20 is carried out in the same manner or in the opposite direction. Similarly, writing then proceeds for the third and subsequent stripe regions 20.

The main deflector 208 sequentially deflects the electron beam 200 to the reference position A of each SF 30 so as to follow the movement of the XY stage 105. The sub-deflector 209 sequentially deflects the electron beam 200 from the reference position A of each SF 30 to the reference position B of the TF 40. The sub-sub deflector 210 deflects the electron beam 200 from the reference position B of each TF 40 to the shot positions 42 of the beam irradiated within the corresponding TF 40.

In this manner, the main deflector 208, the sub-deflector 209, and the sub-sub deflector 210 have deflection regions of different sizes. Among the deflection regions of the multiple-stage deflectors, the TF 40 constitutes the smallest deflection region.

The focus correction lens 240 performs dynamic focus adjustment in response to height variations on the surface of the substrate 101 and is an electrostatic lens. The focus correction lens 240 is arranged downstream in the traveling direction of the electron beam relative to the deflectors (main deflector 208, sub-deflector 209, or sub-sub deflector 210). In addition, the focus correction lens 240 is located within the magnetic field of the objective lens 207.

The focus correction lens 240 has a ring-shaped electrode to which a positive voltage is applied, and the focus correction lens 240 operates within a positive voltage range with respect to the surface of the substrate 101. As a result, reflected electrons and secondary electrons from the substrate 101, onto which the electron beam (primary beam) is irradiated, are attracted toward the electrode, preventing charging of the resist on the surface of the substrate 101.

In an electron beam writing apparatus, a phenomenon called beam drift occurs, in which the irradiation position or shape of the electron beam shifts over time during writing. This phenomenon is caused by contamination adhering to the electrodes of the deflectors becoming charged due to reflected or secondary electrons emitted from the substrate surface and traveling upward within the electron optical column 102, which alters the trajectory of the electron beam.

In the present embodiment, a detector 230 is used to detect the amount of reflected and secondary electrons from the substrate 101, and the amount of charge accumulated on the surfaces of the deflectors (main deflector 208, sub-deflector 209, or sub-sub deflector 210) is calculated from the detection results. Based on the accumulated charge amount, the drift amount is calculated, and the charging-induced drift caused by the charge-up phenomenon of the deflectors is corrected in real time.

Reflected and secondary electrons are deflected by the electric field of the main deflector 208, making it easier for contamination on the electrode surface of the main deflector 208 to become charged. Therefore, it is preferable to place the detector 230 near the main deflector 208 to calculate the amount of charge accumulated on the surface of the main deflector 208. For example, the detector 230 is arranged directly below the main deflector 208.

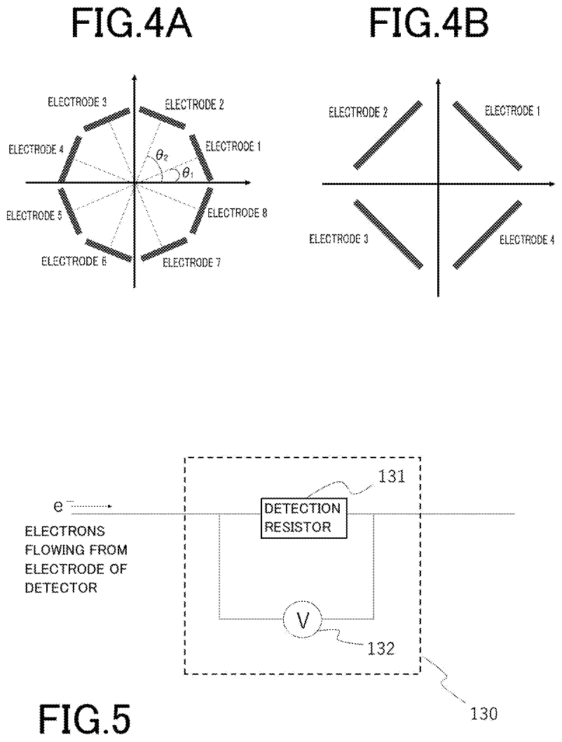

The detector 230 has, for example, a plurality of electrodes corresponding to the multiple electrodes of the main deflector 208 or the like, and the electrodes are arranged at equal intervals so as to surround the beam passage region. FIG. 4A shows an example of the electrode arrangement when the detector 230 has eight electrodes, and FIG. 4B shows an example of the electrode arrangement when the detector 230 has four electrodes.

The detector 230 is connected to the voltage measuring device 130. For example, as shown in FIG. 5, the voltage measuring device 130 includes a resistor 131 and a digital multimeter 132 for measuring the voltage across the resistor 131. When electrons flow into the resistor 131 via the electrodes of the detector 230, a voltage drop occurs. By measuring changes in the voltage with the digital multimeter 132, the current amount from the reflected and secondary electrons detected by each electrode of the detector 230 can be determined. The current amount is transmitted to and input into the control computer 110.

The voltage measuring device 130 continuously measures the current amount, and the drift correction unit 52 calculates the average current amount over a predetermined time. In other words, the drift correction unit 52 calculates the average current amount at predetermined time intervals. The predetermined time is not particularly limited as long as it is sufficiently longer than the duration of one writing shot, and is, for example, about 200 ms.

Let the amount of accumulated charge at the start of the i-th measurement be Qᵢ. The amount of accumulated charge Qᵢ₊₁ at the end of the i-th measurement (or the start of the (i+1)-th measurement) can be expressed by the following equation. In the following equation, Qₘₐₓ is the saturated electron amount, tᵢₙₜ is the measurement time (the predetermined time described above), tₛₕₒₜ is the total beam-on time during the measurement, tₛₜₗ is the total beam-off time during the measurement, τ_{c} is the charging time constant, τ_{d} is the discharging time constant, qₛₕₒₜ is the current amount during beam-on, qₛₜₗ is the current amount during beam-off, and qᵢ is the i-th current measurement result (average current amount).

$${Q}_{i + 1} = exp ( - \frac{{t}_{shot}}{{τ}_{c}} - \frac{{t}_{stl}}{{τ}_{d}} ) [ {Q}_{max} \{ exp ( \frac{{t}_{shot}}{{τ}_{c}} ) - 1 \} + {Q}_{i} ] \qquad [ Equation 1 ]$$

$${t}_{int} = {t}_{shot} + {t}_{stl}$$

$${t}_{shot} = \frac{{q}_{i} - {q}_{stl}}{{q}_{shot} - {q}_{stl}} {t}_{int}$$

$${t}_{stl} = \frac{{q}_{shot} - {q}_{i}}{{q}_{shot} - {q}_{stl}} {t}_{int}$$

$${q}_{i} = \frac{{q}_{shot} {t}_{shot} + {q}_{stl} {t}_{stl}}{{t}_{int}}$$

The current amount during beam-on (shot-on), qₛₕₒₜ, and the current amount during beam-off (shot-off), qₛₜₗ, are measured in advance using the voltage measuring device 130 and obtained beforehand.

The charging caused by reflected and secondary electrons during beam irradiation (beam-on) and the discharging during beam-off vary depending on the pattern density of the pattern to be written on the substrate 101. Accordingly, in advance, while performing pattern writing operations with specific pattern densities, the reflection mark 107 is scanned with the electron beam at fixed time intervals to measure the beam position and acquire data on beam drift. This acquisition of beam drift data is performed for multiple different pattern densities. From the obtained data, the parameter calculation unit 53 calculates parameter values such as the saturated electron amount Qₘₐₓ and the time constants τ_{c} and τ_{d} that reproduce the trend of all beam drift.

In this way, calculation formula data for calculating the accumulated charge, including various parameters such as the previously determined qₛₕₒₜ, qₛₜₗ, Qₘₐₓ, τ_{c} and τ_{d}, is stored in the storage device 140.

The drift correction unit 52 calculates the drift amount using the accumulated charge calculated from the current amounts corresponding to each electrode of the detector 230. For example, as shown in FIG. 4A, when the detector 230 has eight electrodes and the angles of electrodes 1 to 8 with respect to the x-axis are θ₁ to θ₈, the drift amount in the x direction, Dx, and the drift amount in the y direction, Dy, can be determined by the following equations. Q_{i,n} is the amount of accumulated charge on electrode n at the start of the i-th current measurement.

$$Dx = - ( {Q}_{i , 1} * cos ( {θ}_{1} ) + {Q}_{i , 2} * cos ( {θ}_{2} ) + {Q}_{i , 3} * cos ( {θ}_{3} ) + {Q}_{i , 4} * cos ( {θ}_{4} ) + {Q}_{i , 5} * cos ( {θ}_{5} ) + {Q}_{i , 6} * cos ( {θ}_{6} ) + {Q}_{i , 7} * cos ( {θ}_{7} ) + {Q}_{i , 8} * cos ( {θ}_{8} ) )$$

$$Dy = - ( {Q}_{i , 1} * sin ( {θ}_{1} ) + {Q}_{i , 2} * sin ( {θ}_{2} ) + {Q}_{i , 3} * sin ( {θ}_{3} ) + {Q}_{i , 4} * sin ( {θ}_{4} ) + {Q}_{i , 5} * sin ( {θ}_{5} ) + {Q}_{i , 6} * sin ( {θ}_{6} ) + {Q}_{i , 7} * sin ( {θ}_{7} ) + {Q}_{i , 8} * sin ( {θ}_{8} ) )$$

Such calculation formula data for calculating the drift amount is stored in the storage device 140.

The drift correction unit 52 retrieves the calculation formula data from the storage device 140. The drift correction unit 52 monitors the measurements from the voltage measuring device 130, calculates the average current amount at predetermined time intervals, and substitutes the calculated values into the formulas to determine the accumulated charge corresponding to each electrode.

The drift correction unit 52 calculates the drift amount from the accumulated charge of each electrode and determines a drift correction amount to cancel the drift.

The drift correction unit 52 generates correction information for the deflection amount of the electron beam (beam irradiation position and beam shape) based on the drift correction amount and provides it to the writing control unit 54. The writing control unit 54 uses this correction information to provide the correction amounts for the beam position and beam shape to the control circuit 120.

The shot data generation unit 50 performs multiple stages of data conversion processing on the writing data stored in the storage device 140, divides each figure pattern to be written into shot patterns of a size that can be irradiated in a single shot, and generates shot data in a format specific to the writing apparatus. For each shot, the shot data defines, for example, a figure code indicating the type of each shot pattern, the figure size (shot size), shot position, beam-on/off time, and the like. The generated shot data is temporarily stored in the memory 112. The writing control unit 54 transfers the shot data to the control circuit 120.

The control circuit 120 applies deflection voltages to the deflectors for deflection control based on the shot data and the correction amounts for the beam position and beam shape. As a result, the beam irradiation position and beam shape are corrected in the writing unit 150.

Thus, according to the present embodiment, it is possible to detect the amount of reflected and secondary electrons during writing and calculate the drift amount.

The drift correction unit 52 may correct the shot positions and beam shapes in the shot data based on the correction amounts, using the irradiation amount.

A constant positive voltage may be applied to the electrodes of the detector 230 with respect to the surface of the substrate 101 to suppress the retention of secondary electrons.

The deflectors themselves may be used as detectors for reflected and secondary electrons.

In the present embodiment, an example using a detector with multiple electrodes has been described, but a single electrode may also be used. For example, when the charging occurs at a specific location (electrode), the correction amount can be calculated by detecting the amount of electrons with a single electrode of the detector corresponding to that location (electrode).

Furthermore, the drift correction of the present embodiment may be performed together with conventional drift correction based on mark measurements and used to complement the periods between measurements. In that case, the parameters, algorithms, or the like in the present embodiment may be modified based on the difference between the calculated drift amount and the mark measurement results. Additionally, if the drift amount deviation exceeds a predetermined threshold relative to the mark measurement results, the real-time drift correction of the present embodiment may be stopped.

Moreover, after detecting the current amount and calculating the drift amount, the drift correction may be performed immediately (in real time) or with a delay, such as for performing an error check. In that case, the delay for the error check can be made shorter than the delay associated with drift correction using mark measurements.

In the above embodiment, an example using an electron beam as the charged particle beam has been described, but the charged particle beam is not limited to an electron beam and may be a beam using charged particles such as an ion beam.

In the above embodiment, a writing apparatus using a single beam has been described, but a multi-beam writing apparatus may also be used. In that case, the shot data defines the shot positions, on/off times for each individual beam, and the detector detects positional shifts due to drift as well as deviations in the beam array shape.

Although the present invention has been described in detail using specific embodiments, it is apparent to those skilled in the art that various modifications can be made without departing from the spirit and scope of the invention.

### DESCRIPTION OF REFERENCE SIGNS

50 Shot Data Generation Unit
52 Drift Correction Unit
53 Parameter Calculation Unit
54 Writing Control Unit
100 Writing Apparatus
110 Control Computer
150 Writing Unit
160 Control Unit
230 Detector

1. A charged particle beam writing apparatus comprising:
a charged particle beam source configured to emit a charged particle beam that is irradiated onto a substrate to be written;
a deflector configured to deflect the charged particle beam to a desired irradiation position on the substrate;
a detector configured to detect electrons reflected or emitted from the substrate toward the deflector;
a correction amount generation unit configured to calculate a drift amount of the charged particle beam irradiated onto the substrate from a current amount obtained from the detected electrons and a time elapsed from detecting the current to performing correction, and to generate a correction amount for irradiation position misalignment based on the drift amount; and
a control unit configured to correct the irradiation position based on shot data of the charged particle beam generated from writing data and the correction amount.

2. The charged particle beam writing apparatus according to claim 1,
wherein the detector is provided with a plurality of electrodes corresponding to the plurality of deflectors, and
the correction amount generation unit further calculates a drift direction using the respective current amounts obtained from the plurality of electrodes of the detector.

3. The charged particle beam writing apparatus according to claim 1,
wherein, the deflection amount of the deflector or the shot data is corrected based on the correction amount.

4. The charged particle beam writing apparatus according to claim 1,
wherein the deflector comprises:
a first deflector configured to deflect the charged particle beam to a reference position of each of a plurality of first subregions into which a writing region of the substrate is virtually divided in a mesh pattern, following movement of a stage on which the substrate is placed;
a second deflector configured to deflect the charged particle beam from the reference position of each first subregion to a reference position of each of a plurality of second subregions into which the first subregion is virtually divided in a mesh pattern; and
a third deflector configured to deflect the charged particle beam from the reference position of each second subregion to shot positions of the beam irradiated within the second subregion,
wherein the detector is disposed immediately below the first deflector.

5. The charged particle beam writing apparatus according to claim 1, further comprising a focus correction lens that performs focus correction of the charged particle beam according to a surface height of the substrate,
wherein the focus correction lens is an electrostatic lens and operates within a positive voltage range relative to the surface of the substrate.

6. A drift amount calculation method comprising:
emitting a charged particle beam to be irradiated onto a substrate to be written;
deflecting the charged particle beam to a desired irradiation position on the substrate;
generating shot data from writing data, the shot data including a shot position and beam on/off time for each shot;
detecting electrons reflected or emitted from the substrate toward the deflector; and
calculating a first drift amount of the irradiation position of the charged particle beam on the substrate based on a current amount obtained from the detected electrons and a time elapsed from detecting the current to performing correction.

7. The drift amount calculation method according to claim 6, further comprising:
scanning a measurement mark provided on a stage on which the substrate is placed to calculate a second drift amount; and
comparing the first drift amount with the second drift amount.

8. A charged particle beam writing method, comprising:
emitting a charged particle beam to be irradiated onto a substrate to be written;
deflecting the charged particle beam to a desired irradiation position on the substrate;
generating shot data from writing data, the shot data including a shot position and beam on/off time for each shot;
detecting electrons reflected or emitted from the substrate toward the deflector;
calculating a first drift amount of the irradiation position of the charged particle beam on the substrate based on a current amount obtained from the detected electrons and a time elapsed from detecting the current to performing correction;
calculating a correction amount for a positional deviation of irradiation based on the first drift amount; and
correcting the irradiation position based on the shot data and the correction amount.
